(19) United States
(12) Patent Application Publication
(10) Pub. No.: US 2023/0307262 A1
(43) Pub. Date: Sep. 28, 2023

(54) SUBSTRATE PROCESSING APPARATUS AND SUBSTRATE PROCESSING METHOD

(71) Applicant: SHIBAURA MECHATRONICS CORPORATION, Kanagawa (JP)

(72) Inventors: Konosuke HAYASHI, Kanagawa (JP); Koichi HIGUCHI, Kanagawa (JP)

(21) Appl. No.: 18/123,793

(22) Filed: Mar. 20, 2023

(30) Foreign Application Priority Data
Mar. 24, 2022 (JP) 2022048232

(51) Int. Cl. H01L 21/67

(52) U.S. Cl. CPC H01L 21/6708; H01L 21/67253

(57) ABSTRACT

According to one embodiment, a substrate processing apparatus includes: a holding unit that holds a substrate; a driving unit that is provided in the holder and rotates the substrate together with the holder; a supply unit that supplies a processing liquid to a target surface of the substrate; a first cup provided to surround the substrate; a second cup provided to surround the first cup and having an inner wall surface having a property different from a property of an inner wall surface of the first cup; and a movement controller that moves the first cup and the second cup such that the processing liquid scattered from the substrate is received either on the inner wall surface of the first cup or on the inner wall surface of the second cup.

### CROSS-REFERENCE TO RELATED APPLICATIONS

This application is based on and claims priority from Japanese Patent Application No. 2022-048232 filed on Mar. 24, 2022 with the Japanese Patent Office, the disclosure of which is incorporated herein in its entirety by reference.

### TECHNICAL FIELD

The present disclosure relates to a substrate processing apparatus and a substrate processing method.

### BACKGROUND

In the related art, a single-wafer type substrate processing apparatus has been known in which an etching processing or a cleaning processing is performed by supplying a processing liquid to a target surface of a substrate such a semiconductor wafer while rotating the substrate. The substrate processing apparatus includes a substrate holding unit, a rotation driving unit, a processing liquid supply unit, and a processing liquid recovering unit. The substrate holding unit holds an end portion of the substrate by a chuck pin provided on a table. The rotation driving unit rotates the substrate together with the substrate holding unit. The processing liquid supply unit ejects the processing liquid toward a target surface of the rotating substrate. The processing liquid recovering unit recovers the processing liquid that is scattered from the rotating substrate. Specifically, the scattered processing liquid is received by a cup provided to surround the rotation driving unit. The processing liquid flows in a downward direction along the inner wall surface of the cup, is recovered from a pipe provided in a bottom portion of the cup, and is reused.

Generally, the substrate processing is performed by switching a plurality of types of processing liquids. For this reason, with regard to the cup that receives the processing liquid as disclosed in, for example, Japanese Patent Laid-Open Publication No. 2009-110985, a technique is known in which the processing liquid scattered from the substrate can be received for each type of the processing liquid by moving the cup in an up and down direction thereby changing the height of the cup.

### SUMMARY

When the substrate processing is performed by a plurality of types of processing liquids, the processing liquid may remain and stay on the inner wall surface of the cup due to, for example, the difference in the viscosities of the processing liquids. When a newly scattered processing liquid collides with the processing liquid remaining and staying on the inside of the cup, the processing liquid bursts (e.g., spatter) and becomes mist. The mist-like processing liquid may be scattered to the outside of the cup or may bounce back to the side of the substrate and adhere to the substrate. In particular, there is a problem that the mist of the processing liquid adhering to the substrate is dried leading to a product defect.

The present disclosure provides a substrate processing apparatus and a substrate processing method capable of suppressing the generation of the mist due to the collision of the processing liquid remaining and staying on the inner wall surface of the cup with a newly scattered processing liquid, thereby preventing the mist from adhering to the substrate.

A substrate processing apparatus according to the present disclosure includes: a holding unit that holds a substrate; a driving unit that is provided in the holding unit and rotates the substrate together with the holding unit; a supply unit that supplies a processing liquid to a target surface of the substrate; a first cup provided to surround the substrate; a second cup provided to surround the first cup and having an inner wall surface having a property different from a property of an inner wall surface of the first cup; and a movement control unit that moves the first cup and the second cup such that the processing liquid scattered from the substrate is received either on the inner wall surface of the first cup or on the inner wall surface of the second cup.

A substrate processing method according to the present disclosure includes: holding a substrate; rotating the substrate that is held; supplying a processing liquid to a target surface of the substrate; and moving a first cup provided to surround the substrate and a second cup provided to surround the first cup and including an inner wall surface having a property different from a property of an inner wall surface of the first cup such that the processing liquid scattered from the substrate is received either on the inner wall surface of the first cup or on the inner wall surface of the second cup.

According to the substrate processing apparatus and the substrate processing method according to the present disclosure, it is possible to suppress the generation of the mist due to the collision of the processing liquid remaining and staying on the inner wall surface of the cup with a newly scattered processing liquid, thereby preventing the mist from adhering to the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a substrate processing apparatus according to an embodiment.

FIG. 2 is a view illustrating the substrate processing apparatus according to the embodiment in a state where a first cup is moved in a downward direction.

FIG. 3 is a view illustrating a control unit according to the embodiment.

FIG. 4 is a flowchart illustrating an operation of the substrate processing apparatus according to the embodiment.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

(Configuration)

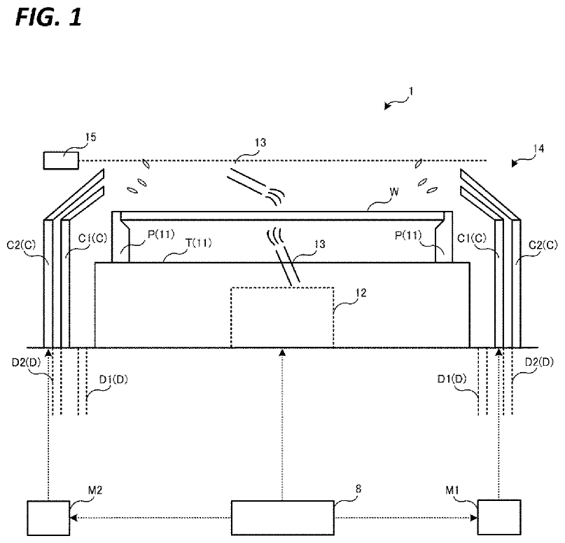

Hereinafter, embodiments of the present disclosure will be described with reference to the drawings. As illustrated in FIG. 1, a substrate processing apparatus 1 of the present embodiment is a single-wafer type substrate processing apparatus that performs an etching processing or a cleaning processing by supplying a processing liquid to a surface (hereinafter, also referred to as a “target surface”) of a substrate W such as a semiconductor wafer. The substrate processing apparatus 1 includes a holding unit 11 that holds the substrate W, a driving unit 12 that rotates the substrate W together with the holding unit 11, supply units 13 that supply the processing liquid to the substrate W, a discharging unit 14 that discharges the processing liquid supplied to the substrate W, and a detecting unit 15 that detects the processing liquid that is scattered from the substrate W, is received by a cup C (to be described later), and bounces back. The substrate processing apparatus 1 includes a control unit 8 (to be described later), and is controlled by the control unit 8.

The holding unit 11 includes a table T and a chuck pin P provided on an upper surface of the table T. The table T is, for example, a cylindrical stage. The chuck pin P is provided on the upper surface of the table T, and holds an edge of the substrate W.

The driving unit 12 is provided in the holding unit 11. The driving unit 12 rotates the holding unit 11 and the substrate W held by the holding unit 11 around an axis perpendicular to the substrate W by, for example, a driving source such as a motor. The number of rotations of the substrate W is controlled by the control unit 8.

The supply unit 13 is a nozzle provided to face a surface of the substrate W, and configured to eject the processing liquid toward the surface of the substrate W that is rotating by the driving unit 12. A single supply unit 13 or a plurality of supply units 13 may be provided for each surface of the substrate W. In the following, descriptions will be made on a case where a single supply unit 13 is provided for each surface. The nozzle facing the surface (e.g., front surface) of both surfaces of the substrate W, which faces the same direction to the upper surface of the table T, is connected to a nozzle moving mechanism (not illustrated) so as to reciprocate between an ejection position facing a center of the front surface of the substrate W and a standby position radially outward of the substrate W from the ejection position. The nozzle facing the surface (e.g., back surface) of both surfaces of the substrate W that faces the upper surface of the table T is provided in a hollow portion (not illustrated) provided in a center of the table T. The nozzle is provided immovably so as not to be affected by the driving unit 12 and so as not to be rotated together with the table T. The control unit 8 controls the movement of the nozzle and the supply amount of the processing liquid.

Examples of the processing liquid of the present embodiment may include buffered hydrogen fluoride (BHF), deionized water (DIW), ozone water, and hydrogen fluoride (HF).

BHF is an aqueous solution obtained by mixing an aqueous solution of high-purity hydrofluoric acid and an aqueous solution of ammonium fluoride. BHF is used as an etching liquid for removing an oxide film formed on the surface of the substrate W, or metal impurities adhering to the surface (e.g., target surface) of the substrate W. Further, BHF has a relatively high viscosity.

DIW is pure water that contains almost no impurities. DIW is used as a rinse liquid for removing the etching liquid from the substrate W. Further, DIW has a relatively low viscosity.

Ozone water is an aqueous solution of ozone. Ozone water is used to form an oxide film on the surface of the substrate W where the oxide film is removed by BHF or HF so that Si is exposed. Further, ozone water has a relatively low viscosity.

HF is an aqueous solution of hydrofluoric acid. Similarly to BHF, HF is used as an etching liquid for removing an oxide film formed on the surface of the substrate W, or metal impurities adhering to the surface of the substrate W. Further, HF has a relatively low viscosity.

The discharging unit 14 is a container that receives the processing liquid scattered from the surface of the substrate W and discharges the received processing liquid. The discharging unit 14 is provided to surround the substrate W held by the driving unit 12, and includes a cup C that receives the processing liquid scattered from the surface of the substrate W, and a pipe D that is provided in a bottom portion of the cup C and discharges the processing liquid that has traveled along an inner wall surface of the cup C.

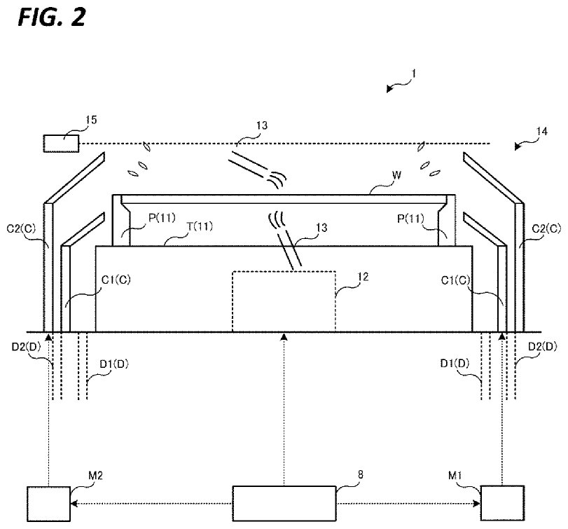

The cup C includes a first cup C1 and a second cup C2. The first cup C1 and the second cup C2 have a cylindrical shape including an opening that exposes the surface (e.g., front surface) of the substrate W, and both the first cup C1 and second cup C2 are provided to surround the substrate W. The second cup C2 has a diameter larger than that of the first cup C1, and is provided to surround the first cup C1. Upper wall surfaces that form the openings of the first cup C1 and the second cup C2 are bent so as to be inclined radially inward. A tip of the portion that is bent (hereinafter, also referred to as a “bent portion”) is provided close to the holding unit 11 that holds the substrate W. As will be described later, a first pipe D1 and a second pipe D2 are provided in the first cup C1 and the second cup C2, respectively, so as to discharge the processing liquid flowing along the inner wall surface of each of the first cup C1 and the second cup C2. The processing liquid received by the inner wall surface of the second cup C2 is prevented from accidently flowing into the first pipe D1 by the upper surface of the bent portion of the first cup C1 (see, e.g., FIG. 2).

The inner wall surface of the first cup C1 includes, for example, countless fine grooves, and is hydrophilic. The inner wall surface of the second cup C2 is, for example, coated with PFA, or contains PTFE, and is hydrophobic. In this manner, the properties of the inner wall surfaces of the first cup C1 and second cup C2 are different from each other.

The first cup C1 includes a movement mechanism M1. The movement mechanism M1 is controlled by the control unit 8, and moves the first cup C1 up and down. The second cup C2 includes a movement mechanism M2. The movement mechanism M2 is controlled by the control unit 8, and moves the second cup C2 up and down. As illustrated in FIG. 1, when the first cup C1 has been moved up, the processing liquid scattered from the substrate W is received by the inner wall surface of the first cup C1. Meanwhile, as illustrated in FIG. 2, when the second cup C2 has been moved up, and the first cup C1 has been moved down, the inner wall surface of the second cup C2 is exposed to the processing liquid scattered from the substrate W. Therefore, the processing liquid scattered from the substrate W is received by the inner wall surface of the second cup C2.

Hereinafter, descriptions will be made on the knowledge discovered by the present inventors regarding the relationship between the viscosity of the processing liquid and the property of the inner wall surface of the cup C.

When receiving a processing liquid having a high viscosity, the processing liquid is likely to remain and stay on the inner wall surface of the cup C as compared to the case of receiving a processing liquid having a low viscosity. For this reason, the high-viscosity processing liquid is likely to remain and stay in a raised state (e.g., a state where the contact angle of the droplet is large) on the inner wall surface of the cup C, compared to the low-viscosity processing liquid. When a processing liquid that is newly scattered from the substrate W collides with the processing liquid in a raised state, the processing liquid bursts due to the impact, and is fragmented into mist. The mist-like processing liquid bounces back to the side of the substrate W due to the impact of the collision and adheres to the target surface of the substrate W, which may cause a manufacturing defect.

The high-viscosity processing liquid is less likely to burst due to the relatively high viscosity. However, as described above, when the droplet remaining staying on the inner wall surface of the cup C in a raised state collides with the processing liquid that is newly scattered from the substrate W, the shape of the droplet collapses and the processing liquid bursts, and thus, becomes mist. At this time, when the inner wall surface of the cup C is hydrophilic, the processing liquid received on the inner wall surface remains so as to be spread over the inner wall surface of the cup C. That is, as compared to the case where the inner wall surface of the cup C is hydrophobic, the processing liquid received on and adhering to the inner wall surface is likely to have a flat shape (e.g., a state where the contact angle of the droplet is small). Even if the processing liquid adhering in such flat shape collides with the processing liquid that is newly scattered from the substrate W, the shape of the processing liquid is less likely to collapse, and thus, the processing liquid may be less likely to burst and become mist. That is, the possibility that the processing liquid becomes mist due to the impact of the collision, and bounces back to the side of the substrate W, is reduced. Therefore, the high-viscosity processing liquid may be received by the first cup C1, which is hydrophilic.

Meanwhile, even in a case where the low-viscosity processing liquid is received by the cup C having the hydrophilic inner wall surface, the low-viscosity processing liquid is likely to have a flat shape (e.g., a state where the contact angle of the droplet is small) on the inner wall surface of the cup C. However, the low-viscosity processing liquid is more likely to burst than the high-viscosity processing liquid due to the viscosity of the processing liquid itself. That is, when the processing liquid that is newly scattered from the substrate W collides with the low-viscosity processing liquid remaining on the inner wall surface of the cup C, the low-viscosity processing liquid is likely to burst due to the impact and become mist. At this time, when the inner wall surface of the cup C is hydrophobic, the low-viscosity processing liquid has a weak force to adhere to the inner wall surface of the cup C due to the relatively low viscosity, thereby forming a liquid droplet (e.g., a state where the contact angle of the droplet is large). That is, even though the amount is small, the processing liquid is less likely to remain on the inner wall surface of the cup C, and is likely to flow down along the inner wall surface of the cup C. For this reason, the possibility that the processing liquid remaining on the inner wall surface of the cup C collides with the processing liquid that is newly scattered from the substrate W, is suppressed, and thus, the processing liquid is less likely to become mist. Since the processing liquid is less likely to become mist, the possibility that the processing liquid bounces back to the side of the substrate W and adheres to the substrate W, is suppressed. Therefore, the low-viscosity processing liquid may be received by the second cup C2, which is hydrophobic.

As described above, the possibility that the processing liquid becomes mist may be suppressed by appropriately using the first cup C1 having the hydrophilic inner wall surface and the second cup C2 having the hydrophobic inner wall surface, according to the viscosity of the processing liquid, to receive the processing liquid. Since the processing liquid is less likely to become mist, the possibility that the processing liquid bounces back to the side of the substrate W and adheres to the substrate W, is suppressed. Determination on which property of the inner wall surface of the cup C is suitable for receiving which processing liquid, may be made by measuring the generated amount of mist through experiments in advance. In the present embodiment, the first cup C1 having the hydrophilic inner wall surface is used to receive the processing liquid such as BHF, and the second cup C2 having the hydrophobic inner wall surface is used to receive the processing liquid such as DIW, ozone water, and HF.

The pipe D includes a first pipe D1 provided in the bottom surface of the first cup C1 and a second pipe D2 provided in the bottom surface of the second cup C2 outside the first cup C1. The first pipe D1 discharges (drains) the processing liquid that has traveled along the inner wall surface of the first cup C1. The second pipe D2 discharges (drains) the processing liquid that has traveled along the inner wall surface of the second cup C2. Specifically, the first pipe D1 and the second pipe D2 are each connected to a gas-liquid separating device (not illustrated). The processing liquid that has traveled along the inner wall surface of the cup C is sent to a recovery tank of the processing liquid or a drainage facility of the plant by the gas-liquid separating device, and discharged. Further, the gas-liquid separating device may change the liquid sending destination according to the type of the processing liquid, and thus, the processing liquid may be discharged for each type. An exhaust gas may be sent to an exhaust facility of the plant by the gas-liquid separating device, and discharged.

The detecting unit 15 is, for example, a sensor such as a photoelectric sensor. In the following, the detecting unit 15 will be described as a reflective photoelectric sensor in which a light projecting unit and a light receiving unit are integrated. The detecting unit 15 is provided at a position that is above the cup C and does not interfere with the operation of moving the cup C up and down. Further, the detecting unit 15 is provided such that an optical axis thereof is parallel with the surface of the substrate W. The height of the optical axis of the detecting unit 15 is, for example, slightly higher than the upper end of the cup C that has been moved up. The detecting unit 15 detects the droplet (hereinafter, also referred to as “mist”) that is scattered from the substrate W, is received on the inner wall surface of the cup C, and bounces back from the inner wall surface of the cup C to the side of the substrate W. Therefore, the detecting unit 15 detects the droplet (mist) of the processing liquid bouncing back to the height that reaches the optical axis. When the detecting unit 15 detects a predetermined amount or more of the droplet of the processing liquid, the control unit 8 controls the driving unit 12 to reduce the number of rotations of the substrate W and controls the supply unit 13 to decrease the supply amount of the processing liquid.

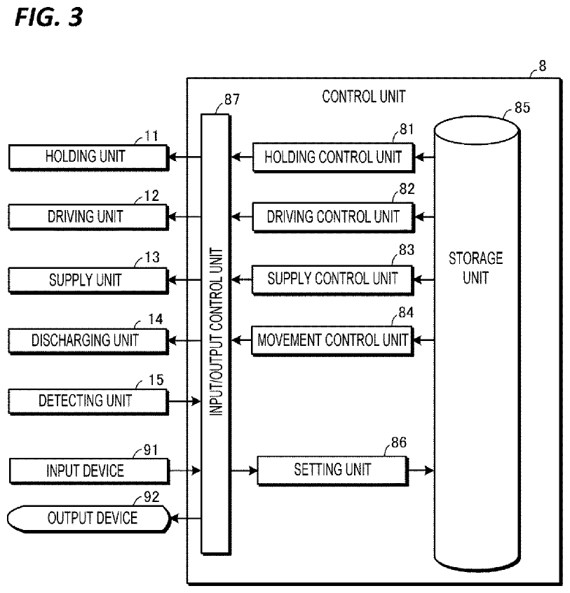

The control unit 8 is, for example, constituted by a dedicated electronic circuit or a computer that is operated by a predetermined program, and controls each component of the substrate processing apparatus 1. As illustrated in FIG. 3, the control unit 8 includes a holding control unit 81, a driving control unit 82, a supply control unit 83, a movement control unit 84, a storage unit 85, a setting unit 86, and an input/output control unit 87.

The holding control unit 81 controls the holding unit 11 to hold the substrate W. The driving control unit 82 controls the driving unit 12 to rotate or stop the substrate W. Further, the driving control unit 82 controls the driving unit 12 to change the number of rotations of the substrate W. For example, when the detecting unit 15 detects a predetermined amount or more of the droplet of the processing liquid, the number of rotations of the substrate W is reduced.

The supply control unit 83 controls the supply unit 13 to move the nozzle, and to supply the processing liquid or stop the supply of the processing liquid as well. Further, the supply control unit 83 controls the supply unit 13 to change the supply amount of the processing liquid. For example, when the detecting unit 15 detects a predetermined amount or more of the droplet of the processing liquid, the supply control unit 13 reduces the supply amount of the processing liquid.

The movement control unit 84 controls the first cup C1 and the second cup C2 provided in the discharging unit 14. Specifically, the movement control unit 84 controls the movement mechanism M1 provided in the first cup C1 and the movement mechanism M2 provided in the second cup C2 to move the first cup C1 and the second cup. For example, by moving the first cup C1 up and down in a state where the first cup C1 and second cup C2 are raised, it is possible to select whether to receive the processing liquid scattered from the substrate W on the inner wall surface of the first cup C1 or on the inner wall surface of the second cup C2. That is, the movement control unit 84 moves the first cup C1 and the second cup C2 such that the processing liquid scattered from the substrate W is received either on the inner wall surface of the first cup C1 or on the inner wall surface of the second cup C2. Therefore, it is possible to select the cup C that is less likely to generate mist according to the type of the processing liquid. Further, the processing liquid may be discharged for each type by the pipe D provided in the bottom portion of the selected cup C.

The storage unit 85 is a recording medium such as an HDD or an SSD. The storage unit 85 stores data and a program necessary for the operation of a system in advance, and stores data necessary for the operation of the system as well. The setting unit 86 is a processing unit that sets information in the storage unit 85 according to the input. The input/output control unit 87 is an interface that controls conversion of signals or input/output between each of the components that are control targets.

The control unit 8 is connected to an input device 91 and an output device 92. The input device 91 is an input unit such as a switch, a touch panel, a keyboard, or a mouse for operating the substrate processing apparatus 1 via the control unit 8 by an operator. The operator may input various information set in the storage unit 85 via the input device 91. The output device 92 is an output unit such as a display, a lamp, or a meter that makes information visible to the operator to check the status of the apparatus. For example, the output device 92 may display an input screen for the information from the input device 91.

(Operation)

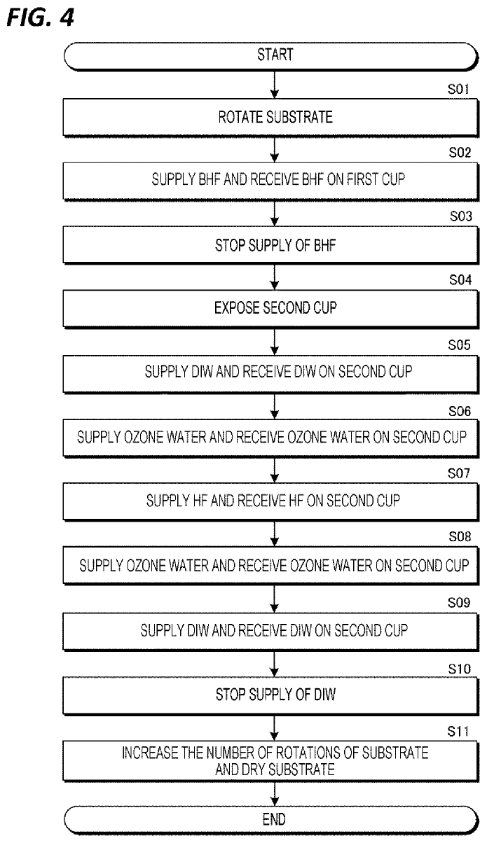

The operation of the substrate processing apparatus 1 will be described with reference to a flowchart in FIG. 4. It is assumed that the substrate W is held by the chuck pin P provided on the table T of the holding unit 11. Further, as illustrated in FIG. 1, the first cup C1 and second cup C2 are moved up by the movement mechanism M1 and movement mechanism M2. That is, the processing liquid scattered from the substrate W is received on the inner wall surface of the first cup C1. This premise is implemented by first lowering the first cup C1 and second cup C2 to transfer the substrate W to the substrate processing apparatus 1, and subsequently, holding the substrate W by the holding unit 11, and then, raising the first cup C1 and second cup C2.

First, the driving control unit 82 controls the driving unit 12 to rotate the substrate W at a predetermined number of rotations (step S01). Next, the supply control unit 83 controls the supply unit 13 to supply a predetermined amount of BHF to the target surface of the substrate W, and causes the BHF scattered from the substrate W to be received by the first cup C1, which is hydrophilic (step S02). The BHF received by the first cup C1 having the hydrophilic inner wall surface is drained from the first pipe D1. At this time, the BHF having a relatively high viscosity remains so as to be spread over the inner wall surface of the first cup C1, so that the BHF is likely to have a flat shape (e.g., a state where the contact angle of the droplet is small). Therefore, the generation of mist and the bounce back to the side of the substrate W due to the collision with the BHF that is newly scattered, are suppressed. Therefore, the mist may be suppressed from adhering to the target surface of the substrate W.

When the substrate W is etched by BHF for a predetermined time, the supply control unit 83 controls the supply unit 13 to stop the supply of BHF (step S03). Continuously, as illustrated in FIG. 2, the movement control unit 84 controls the discharging unit 14 to move the first cup C1 down to expose the second cup C2 that is being moved up in advance (step S04). When the second cup C2 is exposed, the supply control unit 83 controls the supply unit 13 to switch the supply of the processing liquid from BHF to DIW and supply a predetermined amount of DIW to the surface of the substrate W in order to remove BHF from the substrate W, and causes the DIW to be received by the second cup C2 having the hydrophobic inner wall surface (step S05). The DIW received by the second cup C2 travels downward along the inner wall surface of the second cup C2, and is drained from the second pipe D2. At this time, the DIW having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the DIW flows sequentially without remaining on the inner wall surface of the second cup C2, the possibility of the collision with the DIW that is newly scattered, is suppressed. Therefore, the generation of mist and the bounce back to the side of the substrate W are suppressed, so that the mist may be suppressed from adhering to the target surface of the substrate W.

When the substrate W is rinsed by DIW for a predetermined time, the supply control unit 83 controls the supply unit 13 to stop the supply of DIW. The movement control unit 84 maintains the state where the first cup C1 is lowered and the second cup C2 is raised. Next, the supply control unit 83 controls the supply unit 13 to switch the supply of the processing liquid from DIW to ozone water and supply a predetermined amount of ozone water to the surface of the substrate W in order to form an oxide film on the target surface of the substrate W, and causes the ozone water to be received by the second cup C2 having the hydrophobic inner wall surface (step S06). The ozone water received by the second cup C2 travels downward along the inner wall surface of the second cup C2, and is drained from the second pipe D2. At this time, the ozone water having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the ozone water flows sequentially without remaining on the inner wall surface of the second cup C2, the possibility of the collision with the ozone water that is newly scattered, is suppressed. Therefore, the generation of mist and the bounce back to the side of the substrate W are suppressed, so that the mist may be suppressed from adhering to the target surface of the substrate W.

When the formation of the oxide film on the substrate W by ozone water is performed for a predetermined time, the supply control unit 83 controls the supply unit 13 to stop the supply of ozone water. The movement control unit 84 maintains the state where the first cup C1 is lowered and the second cup C2 is raised. Next, the supply control unit 83 controls the supply unit 13 to switch the supply of the processing liquid from ozone water to HF and supply a predetermined amount of HF to the target surface of the substrate W in order to remove the oxide film from the substrate W, and causes the HF to be received by the second cup C2 having the hydrophobic inner wall surface (step S07). The HF received by the second cup C2 travels downward along the inner wall surface of the second cup C2, and is drained from the second pipe D2. At this time, the HF having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the HF flows sequentially without remaining on the inner wall surface of the second cup C2, the possibility of the collision with the HF that is newly scattered, is suppressed. Therefore, the generation of mist and the bounce back to the side of the substrate W are suppressed, so that the mist may be suppressed from adhering to the target surface of the substrate W.

When the substrate W is etched by HF for a predetermined time, the supply control unit 83 controls the supply unit 13 to stop the supply of HF. The movement control unit 84 maintains the state where the first cup C1 is lowered and the second cup C2 is raised. Next, the supply control unit 83 controls the supply unit 13 to switch the supply of the processing liquid from HF to ozone water and supply a predetermined amount of ozone water to the target surface of the substrate W in order to form an oxide film on the substrate W, and causes the ozone water to be received by the second cup C2 having the hydrophobic inner wall surface (step S08). The ozone water received by the second cup C2 travels downward along the inner wall surface of the second cup C2, and is drained from the second pipe D2. At this time, the ozone water having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the ozone water flows sequentially without remaining on the inner wall surface of the second cup C2, the possibility of the collision with the ozone water that is newly scattered, is suppressed. Therefore, the generation of mist and the bounce back to the side of the substrate W are suppressed, so that the mist may be suppressed from adhering to the target surface of the substrate W.

When the formation of the oxide film on the substrate W by ozone water is performed for a predetermined time, the supply control unit 83 controls the supply unit 13 to stop the supply of ozone water. The movement control unit 84 maintains the state where the first cup C1 is lowered and the second cup C2 is raised. Next, the supply control unit 83 controls the supply unit 13 to switch the supply of the processing liquid from ozone water to DIW and supply a predetermined amount of DIW to the target surface of the substrate W in order to remove HF from the substrate W, and causes the DIW to be received by the second cup C2 having the hydrophobic inner wall surface (step S09). The DIW received by the second cup C2 travels downward along the inner wall surface of the second cup C2, and is drained from the second pipe D2. At this time, the DIW having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the DIW flows sequentially without remaining on the inner wall surface of the second cup C2, the possibility of the collision with the DIW that is newly scattered, is suppressed. Therefore, the generation of mist and the bounce back to the side of the substrate W are suppressed, so that the mist may be suppressed from adhering to the target surface of the substrate W.

When the substrate W is rinsed by DIW for a predetermined time, the supply control unit 83 controls the supply unit 13 to stop the supply of DIW (step S10). Finally, the driving control unit 82 controls the driving unit 12 to increase the number of rotations of the substrate W (step S11). Therefore, DIW is shaken off from the substrate W, and the substrate W is dried. The DIW shaken off is received by the inner wall surface of the second cup C2, and is drained from the second pipe D2. At this time, the DIW having a relatively low viscosity has a weak force to adhere to the inner wall surface of the second cup C2, which is hydrophobic, due to the relatively low viscosity, thereby forming a liquid droplet (e.g., a state where the contact angle of the droplet is large). That is, since the DIW flows sequentially without remaining on the inner wall surface of the second cup C2, the possibility of the collision with the DIW that is newly scattered, is suppressed. Therefore, the generation of mist and the bounce back to the side of the substrate W are suppressed, so that the mist may be suppressed from adhering to the target surface of the substrate W.

Further, in the processing of the substrate W in step S01 to step S11 described above, when the detecting unit 15 detects a predetermined amount or more of the droplet of the processing liquid, the driving control unit 82 may control the driving unit 12 to reduce the number of rotations of the substrate W, and the supply control unit 83 may control the supply unit 13 to decrease the supply amount of the processing liquid. Therefore, the momentum of the processing liquid received on the inner wall surface of the cup C is suppressed, and further, the amount of the processing liquid is decreased as well, and thus, even when the mist is not sufficiently suppressed when selecting the cup C having the inner wall surface suitable for the viscosity of the processing liquid, the generation of the mist and the bounce back to the side of the substrate W due to the collision with the processing liquid may be efficiently suppressed. Therefore, the mist is efficiently suppressed from adhering to the target surface of the substrate W.

The number of rotations of the substrate W may be reduced uniformly to a predetermined number of rotations, or may be gradually reduced until the detecting unit 15 no longer detects a predetermined amount or more of the droplet of the processing liquid. In this case, the number of rotations of the substrate W may be maintained at the time when the detecting unit 15 no longer detects a predetermined amount or more of the droplet of the processing liquid.

The supply amount of the processing liquid may be decreased uniformly to a predetermined supply amount, or may be gradually decreased until the detecting unit 15 no longer detects a predetermined amount or more of the droplet of the processing liquid. In this case, the supply amount of the processing liquid may be maintained at the time when the detecting unit 15 no longer detects a predetermined amount or more of the droplet of the processing liquid.

Further, the number of rotations of the substrate W that is held and the supply amount of the processing liquid at the time when the detecting unit 15 no longer detects a predetermined amount or more of the droplet of the processing liquid are stored in the storage unit 85, and are used for the subsequent processing of the substrate W. In the subsequent processing of the substrate W, when the detecting unit 15 detects a predetermined amount of the droplet of the processing liquid again, the number of rotations of the substrate W or the supply amount of the processing liquid may be adjusted again, and the number of rotations of the substrate W or the supply amount of the processing liquid, which is adjusted, may be newly used.

(Effect)

(1) The substrate processing apparatus 1 according to the present embodiment includes: the holding unit 11 that holds the substrate W; the driving unit 12 that is provided in the holding unit 11 and rotates the substrate W together with the holding unit 11; the supply unit 13 that supplies the processing liquid to the target surface of the substrate W to process the substrate W; the first cup C1 provided to surround the substrate W; the second cup C2 provided to surround the first cup C1 and having the inner wall surface having the property different from the property of the inner wall surface of the first cup C1; and the movement control unit 84 that moves the first cup C1 and the second cup C2 such that the processing liquid scattered from the substrate W is received either on the inner wall surface of the first cup C1 or on the inner wall surface of the second cup C2. Therefore, it is possible to select the cup C that includes the inner wall surface suitable for receiving the processing liquid according to the viscosity of the processing liquid. For example, for a high-viscosity processing liquid that is received on and remains on the inner wall surface of the cup C, the cup C capable of reducing the contact angle of the droplet on the inner wall surface may be selected, and for a low-viscosity processing liquid that is likely to burst and become mist when received on the cup C, the cup C on which the processing liquid is less likely to remain on the inner wall surface may be selected. Therefore, it is possible to suppress the possibility that the processing liquid remaining on the inner wall surface collides with the processing liquid that is newly scattered to generate mist, or to suppress the possibility of the collision with the processing liquid that is newly scattered by making the processing liquid not stay on the inner wall surface, thereby suppressing the generation of mist. In either case, the generation of mist may be suppressed, and thus, the mist may be suppressed from adhering to the target surface of the substrate W.

(2) The inner wall surface of the first cup C1 of the present embodiment is hydrophilic, and the inner wall surface of the second cup C2 is hydrophobic. Therefore, the processing liquid such as BHF having a relatively high viscosity is received by the inner wall surface of the first cup C1, which is hydrophilic. Therefore, the contact angle of the processing liquid on the inner wall surface is reduced, and thus, it is possible to suppress the possibility of the generation of mist due to the collision with the processing liquid that is newly scattered. Further, the processing liquid such as DIW, ozone water, or HF having a relatively low viscosity is received by the inner wall surface of the second cup C2, which is hydrophobic. Therefore, the contact angle of the processing liquid on the inner wall surface is increased, and thus, the processing liquid does not remain on the inner wall surface and it is possible to suppress the possibility of the collision with the processing liquid that is newly scattered. Therefore, the generation of mist may be suppressed. In this manner, in any cases of a high-viscosity processing liquid or a low-viscosity processing liquid, the generation of mist is suppressed, and thus, the mist may be suppressed from adhering to the target surface of the substrate W.

(3) The substrate processing apparatus 1 according to the present embodiment further includes the detecting unit 15 that detects the droplet of the processing liquid that is received either on the inner wall surface of the first cup C1 or on the inner wall surface of the second cup C2, and bounces back toward the side of the substrate W. When the detecting unit 15 detects a predetermined amount or more of the droplet of the processing liquid, the driving unit 12 reduces the number of rotations of the substrate W, and the supply unit 13 decreases the amount of the processing liquid supplied to the substrate W. Therefore, the momentum of the processing liquid received on the inner wall surface of the cup C is suppressed, and further, the amount of the processing liquid is decreased as well, and thus, even when the mist is not sufficiently suppressed when selecting the cup C having the inner wall surface suitable for the viscosity of the processing liquid, the generation of the mist and the bounce back to the side of the substrate W due to the collision with the processing liquid may be efficiently suppressed. Therefore, the mist may be efficiently suppressed from adhering to the target surface of the substrate W.

[Modification]

(1) In the above embodiment, the first cup C1 is hydrophilic and the second cup C2 provided outside the first cup C1 is hydrophobic, but the present disclosure is not limited thereto. The first cup C1 may be hydrophobic and the second cup C2 provided outside the first cup C1 may be hydrophilic. In this case, similarly to the above embodiment, when the processing is first performed by using BHF, which is a high-viscosity processing liquid, and then, the processing is performed by using DIW, ozone water, or HF, which is a low-viscosity processing liquid, in the processing step using BHF, the first cup C1 is moved down so that the second cup C2 is exposed for the processing liquid that is scattered from the substrate W. Therefore, BHF, which has a relatively high viscosity, is received by the second cup C2 that is provided outside and is hydrophilic. Therefore, the contact angle of the processing liquid on the inner wall surface is reduced, and thus, it is possible to suppress the possibility of the generation of mist due to the collision with the processing liquid that is newly scattered. Meanwhile, in the processing step using DIW, ozone water, or HF, the first cup C1 is moved up, so that the first cup C1 faces the processing liquid scattered from the substrate W. Therefore, DIW, ozone water, or HF, which has a relatively low viscosity, is received by the first cup C1, which is hydrophobic, and flows sequentially without remaining on the inner wall surface of the first cup C1. Therefore, since the processing liquid does not remain on the inner wall surface, it is possible to suppress the possibility of the collision with the processing liquid that is newly scattered. Thus, the generation of mist may be suppressed. In either case, the generation of mist may be suppressed, and thus, the mist may be suppressed from adhering to the target surface of the substrate W.

(2) When the detecting unit 15 of the above embodiment detects a predetermined amount or more of the droplet of the processing liquid, the driving control unit 82 controls the driving unit 12 to reduce the number of rotations of the substrate W, and the supply control unit 83 controls the supply unit 13 to decrease the supply amount of the processing liquid, but the present disclosure is not limited thereto. For example, the driving unit 12 reduces the number of rotations of the substrate W, but the supply unit 13 may not decrease the supply amount of the processing liquid. Further, the supply unit 13 decreases the supply amount of the processing liquid, but the driving unit 12 may not reduce the number of rotations of the substrate W. The detecting unit 15 may be omitted and the number of rotations of the substrate W or the supply amount of the processing liquid may not be controlled according to the detection of the detecting unit 15.

(3) The detecting unit 15 of the above embodiment is the reflective photoelectric sensor in which a light projecting unit and a light receiving unit are integrated, but the present disclosure is not limited thereto. For example, a transmissive photoelectric sensor in which a light projecting unit and a light receiving unit are separate bodies, may be used. Further, the detecting unit 15 is not limited to a photoelectric sensor, but may be an infrared (IR) camera, a CCD camera, or a CMOS camera.

(4) The processing liquids of the above embodiment are BHF, DIW, ozone water, and HF, but the present disclosure is not limited thereto. For example, any appropriate processing liquids suitable for processing the substrate W, such as sulfuric acid or phosphoric acid, may be used. Further, the order of using the processing liquids of the above embodiment is an example, and the processing liquids may be used in an arbitrary order. For example, a low-viscosity processing liquid, a high-viscosity processing liquid, and a low-viscosity processing liquid may be used in this order. In this case, for the processing liquid scattered from the substrate W, each of the processing liquids may be received by facing the inner wall surface of the second cup C2, which is hydrophobic, the inner wall surface of the first cup C1, which is hydrophilic, and the inner wall surface of the second cup C2, which is hydrophobic, respectively.

From the foregoing, it will be appreciated that various embodiments of the present disclosure have been described herein for purposes of illustration, and that various Modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus comprising:
a holder configured to hold a substrate;
a rotation driver provided in the holder and configured to rotate the substrate together with the holder;
a processing liquid supply configured to supply a processing liquid to a target surface of the substrate;
a first cup provided to surround the substrate;
a second cup provided to surround the first cup and having an inner wall surface having a property different from a property of an inner wall surface of the first cup; and
a movement controller configured to move the first cup and the second cup such that the processing liquid scattered from the substrate is received either on the inner wall surface of the first cup or on the inner wall surface of the second cup.

2. The substrate processing apparatus according to claim 1, wherein the inner wall surface of the first cup has one of hydrophilic property or hydrophobic property, and
the inner wall surface of the second cup has a remaining one of the hydrophobic property or hydrophilic property.

3. The substrate processing apparatus according to claim 2, wherein the movement controller moves the first cup and the second cup such that
when the processing liquid has a relatively high viscosity, the processing liquid scattered from the substrate is received on the inner wall surface of the first or second cup that is hydrophilic, and
when the processing liquid has a relatively low viscosity, the processing liquid scattered from the substrate is received on the inner wall surface of the first or second cup that is hydrophobic.

4. The substrate processing apparatus according to claim 1, wherein the inner wall surface of the first cup is hydrophilic, and
the inner wall surface of the second cup is hydrophobic.

5. The substrate processing apparatus according to claim 4, wherein the supply is provided to supply a first processing liquid and a second processing liquid to the target surface of the substrate, and
the movement controller is configured to move the first cup and the second cup such that
when the processing liquid scattered from the substrate is the first processing liquid, the first processing liquid scattered from the substrate is received on the inner wall surface of the first cup, and
when the processing liquid scattered from the substrate is the second processing liquid, the second processing liquid scattered from the substrate is received on the inner wall surface of the second cup.

6. The substrate processing apparatus according to claim 5, wherein the first processing liquid has a viscosity higher than that of the second processing liquid.

7. The substrate processing apparatus according to claim 5, wherein the first processing liquid is buffered hydrogen fluoride (BHF), and
the second processing liquid is one of deionized water (DIW), ozone water, and hydrogen fluoride (HF).

8. The substrate processing apparatus according to claim 1, further comprising:
a detector configured to detect a droplet of the processing liquid that is received either on the inner wall surface of the first cup or on the inner wall surface of the second cup, and bounces back toward a side of the substrate,
wherein, when the detector detects a predetermined amount or more of the droplet of the processing liquid, the rotation driver reduces the number of rotations of the substrate.

9. The substrate processing apparatus according to claim 1, further comprising:
a detector configured to detect a droplet of the processing liquid that is received either on the inner wall surface of the first cup or on the inner wall surface of the second cup, and bounces back toward a side of the substrate,
wherein, when the detector detects a predetermined amount or more of the droplet of the processing liquid, the supply decreases a supply amount of the processing liquid supplied to the substrate.

10. The substrate processing apparatus according to claim 1, further comprising:
a detector configured to detect a droplet of the processing liquid that is received either on the inner wall surface of the first cup or on the inner wall surface of the second cup, and bounces back toward a side of the substrate,
wherein, when the detector detects a predetermined amount or more of the droplet of the processing liquid, the rotation driver reduces a number of rotations of the substrate, and the supply decreases a supply amount of the processing liquid supplied to the substrate.

11. A substrate processing method comprising:
holding a substrate;
rotating the substrate that is held;
supplying a processing liquid to a target surface of the substrate; and
moving a first cup provided to surround the substrate and a second cup provided to surround the first cup and having an inner wall surface having a property different from a property of an inner wall surface of the first cup such that the processing liquid scattered from the substrate is received either on the inner wall surface of the first cup or on the inner wall surface of the second cup.
